(19) United States
(12) Patent Application Publication
(10) Pub. No.: US 2026/0293453 A1
(43) Pub. Date: Sep. 24, 2026

(54) DISPLAY DEVICE

(71) Applicant: LG Display Co., Ltd., Seoul (KR)

(72) Inventors: Jinhyeon KIM, Gyeonggi-do (KR); Hoonsok SON, Gyeonggi-do (KR); Beomgon JO, Gyeonggi-do (KR)

(21) Appl. No.: 19/396,930

(22) Filed: Nov. 21, 2025

(30) Foreign Application Priority Data
Mar. 24, 2025 (KR) 10-2025-0037058

(51) Int. Cl. H10K 59/124; H10K 59/12; H10K 59/123; H10K 59/35; H10K 59/80

(52) U.S. Cl. CPC H10K 59/124; H10K 59/1201; H10K 59/123; H10K 59/35; H10K 59/80518

(57) ABSTRACT

A display device includes: a substrate on which a first sub-pixel including a first emission area and a first non-emission area surrounding the first emission area is defined, a first insulating layer on the first non-emission area of the substrate, a first reflective electrode disposed on an upper surface and side surfaces of the first insulating layer and disposed in the first emission area and the first non-emission area, a second insulating layer disposed on the first reflective electrode and exposing an upper surface of the first reflective electrode disposed on the first insulating layer, and a second connection electrode disposed directly on the exposed upper surface of the first reflective electrode.

### CROSS REFERENCE TO RELATED APPLICATION

Pursuant to 35 U.S.C. § 119(a), this application claims the benefit of an earlier filing date and right of priority to Korean Patent Application No. 10-2025-0037058, filed in the Republic of Korea on Mar. 24, 2025, the entire contents of which are hereby expressly incorporated by reference into the present application.

### BACKGROUND

The present specification relates to a display device. Examples of display devices include liquid crystal display (LCD) devices and organic light emitting diode (OLED) display devices.

Unlike LCD devices, OLED display devices are self-luminous. By not requiring separate backlights, OLED display devices can have superior viewing angles and contrast ratios, can be lighter and thinner, and can have low power consumption than LCD devices. In addition, OLED displays can drive at a low direct current voltage, can a fast response speed, and can have low manufacturing costs.

OLED display devices can be used as display devices for augmented reality (AR), virtual reality (VR), or other ultra-high resolution applications.

### SUMMARY

According to one aspect, there is provided a display device that includes: a substrate in which a first sub-pixel including a first emission area and a first non-emission area around the first emission area is defined, a first insulating layer on the first non-emission area of the substrate, a first reflective electrode disposed on an upper surface and side surfaces of the first insulating layer and disposed in the first emission area and the first non-emission area, a second insulating layer disposed on the first reflective electrode and exposing an upper surface of the first reflective electrode disposed on the first insulating layer, and a second connection electrode disposed directly on the exposed upper surface of the first reflective electrode.

Implementations of the present specification are directed to providing a display device with an expandable emission area.

Implementations of the present specification can provide a display device with improved performance by including better performing organic light emitting diodes.

Implementations of present specification can provide a low-power display device.

Implementations and advantages of the present specification are not limited to those described above, and other implementations and advantages will be understood from the following description.

Detailed matters of other implementations of the present specification are included in the detailed description and accompanying drawings.

### BRIEF DESCRIPTION OF THE DRAWINGS

FIG. 1 is a plan view of a display device.

FIG. 2 is a plan view of a pixel of a display device.

FIG. 3 is a cross-sectional view of an implementation of a pixel along line A-A′ of FIG. 2.

FIG. 4 is a cross-sectional view of an implementation of a pixel along line B-B′ of FIG. 2.

FIG. 5 is a cross-sectional view of an implementation of a pixel along line C-C′ of FIG. 2.

FIG. 6 is a cross-sectional view of an implementation of a pixel along line D-D′ of FIG. 2.

FIG. 7 is a cross-sectional view of an implementation of an organic light emitting diode (OLED) of a pixel.

FIG. 8 is a cross-sectional view of another implementation of an organic light emitting diode (OLED) of a pixel.

FIGS. 9 through 14 are a sequence of cross-sectional views for a method of manufacturing a display device.

FIG. 15 is a cross-sectional view of another implementation of a pixel along line B-B′ of FIG. 2.

### DETAILED DESCRIPTION

Hereinafter, implementations of the present disclosure will be described with reference to the accompanying drawings. In the specification, when a certain component (or an area, a layer, a portion, etc.) is described as “on,” “connected,” or “coupled to” another component, it means that the certain component can be directly connected/coupled to another component or still another component can be disposed therebetween.

The same reference numerals indicate the same components. In addition, in the drawings, thicknesses, proportions, and dimensions of components are exaggerated for effective description of technical contents. The term “and/or” includes all one or more combinations that can be defined by the associated configurations.

Terms such as “first,” “second,” and the like can be used to describe various components, but the components are not limited by the terms. The terms are used only for the purpose of distinguishing one component from another. For example, a first component can be referred to as a second component, and similarly, the second component can also be referred to as the first component without departing from the scopes of the described implementations. The singular includes the plural unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings.

It should be understood that term such as “includes” or “has” is intended to specify the presence of features, numbers, steps, operations, components, parts, or a combination thereof described in the specification and does not preclude the presence or addition possibility of one or more other features, numbers, steps, operations, components, parts, or combinations thereof in advance.

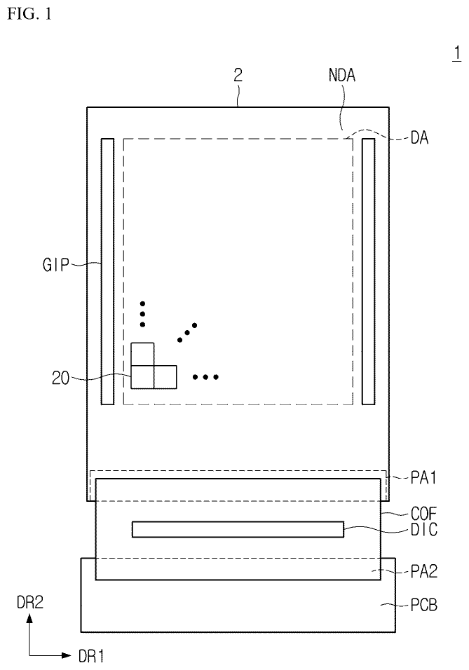

FIG. 1 is a plan view of a display device.

Referring to FIG. 1, a display device 1 can include a display area DA including a plurality of pixels 20, and a non-display area NDA near the display area DA. The non-display area NDA can surround the display area DA and can exclude the pixels 20 and not generate an image, but implementations of the present specification are not limited thereto. The non-display area NDA can include a first pad area PA1 disposed at the other side of the display area DA in a second direction DR2.

A gate driver GIP can be disposed in the non-display area NDA at one side and the other side of the display area DA in the first direction DR1. The gate driver GIP can be formed in the form of an integrated circuit on the substrate 2, but is not limited thereto, and can be formed in the form of a driving chip. FIG. 1 illustrates the gate driver GIP disposed at each of left and right sides of the display area DA, but implementations of the present specification are not limited thereto, and the gate driver GIP can be disposed at only one of the left and right sides.

A connection film COF can be attached to the first pad area PA1. A data driver DIC can be disposed on the connection film COF. The data driver DIC can be provided in the form of a driving chip, but implementations of the present specification are not limited thereto. One end of the connection film COF can be connected to the first pad area PA1, and the other end can include a second pad area PA2. A printed circuit board PCB can be connected to the second pad area PA2 of the connection film COF.

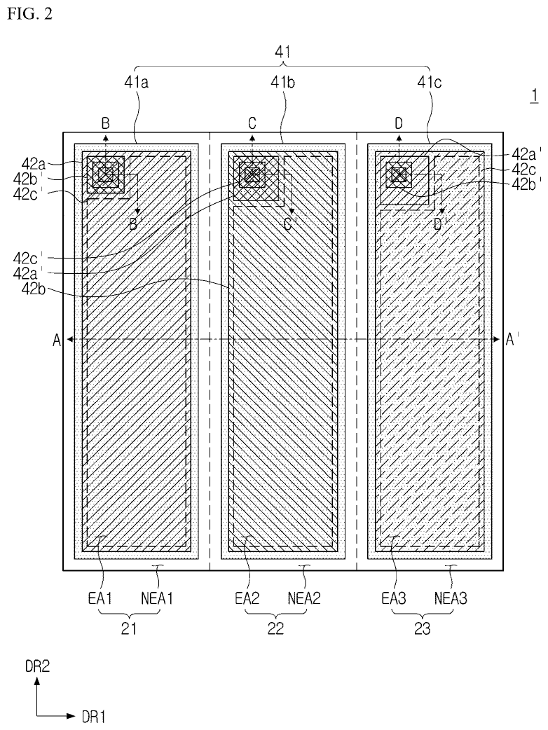

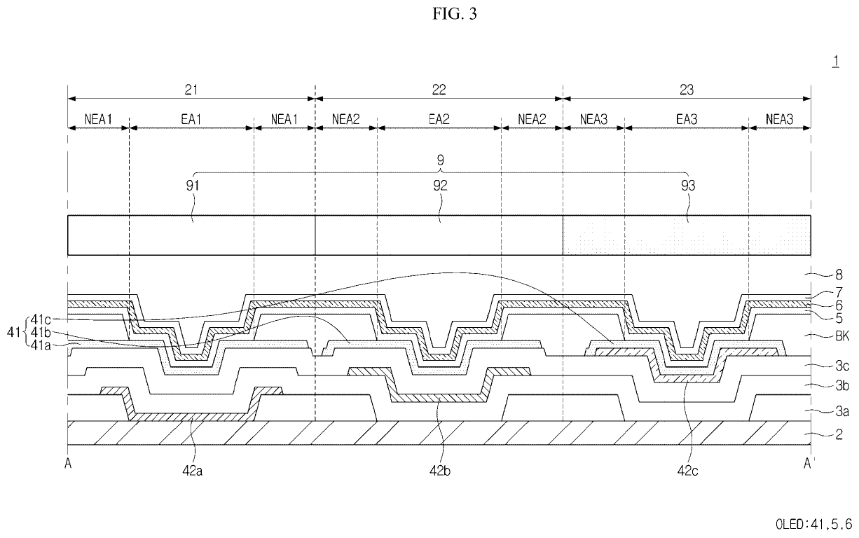

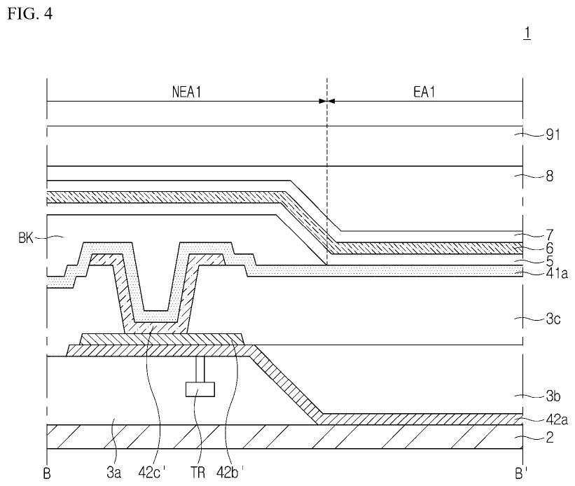

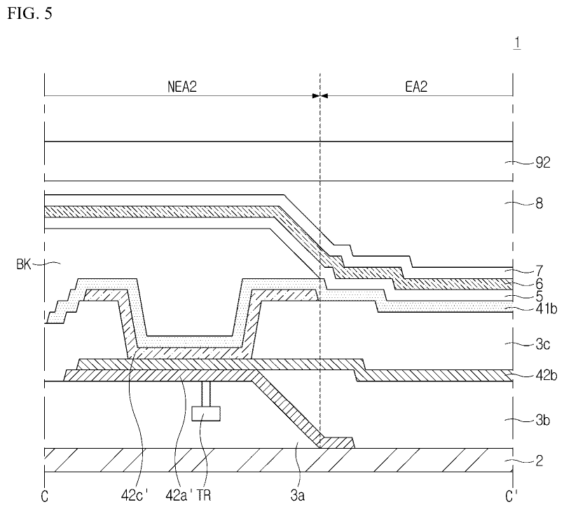

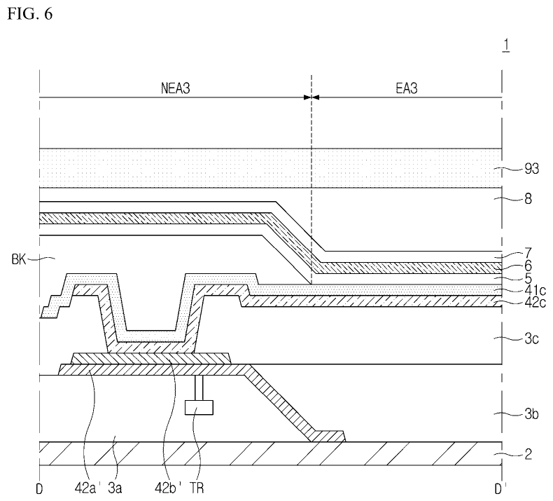

FIG. 2 is a plan view of a pixel of a display device. FIG. 3 is a cross-sectional view of an implementation of a pixel along line A-A′ of FIG. 2. FIG. 4 is a cross-sectional view of an implementation of a pixel along line B-B′ of FIG. 2. FIG. 5 is a cross-sectional view an implementation of a pixel along line C-C′ of FIG. 2. FIG. 6 is a cross-sectional view of an implementation a pixel along line D-D′ of FIG. 2. FIGS. 4 to 6 illustrate areas in contact with the connection electrode (or a reflective electrode) of each sub-pixel.

Referring to FIGS. 2 to 6, the display device 1 can include a substrate 2, first electrodes 41a, 41b, and 41c, a common emission layer 5, and a second electrode 6.

A plurality of sub-pixels 21, 22, and 23 are formed on the substrate 2. The plurality of sub-pixels 21, 22, and 23 can form one pixel 20 (se FIG. 1). The plurality of pixels can be formed on the substrate 2.

The plurality of sub-pixels 21, 22, and 23 include a first sub-pixel 21, a second sub-pixel 22, and a third sub-pixel 23. Since the first sub-pixel 21, the second sub-pixel 22, and the third sub-pixel 23 can be arranged sequentially, the second sub-pixel 22 can be disposed adjacent to one side, for example, the left side of the first sub-pixel 21, and the third sub-pixel 23 can be disposed adjacent to one side, for example, the left side of the second sub-pixel 22.

Throughout the present specification, when two sub-pixels are disposed adjacent to each other, it should be construed to mean that no other sub-pixels are disposed between the two sub-pixels.

The first sub-pixel 21 can be provided to emit red (R) light, the second sub-pixel 22 can be provided to emit blue (g) light, and the third sub-pixel 23 can be provided to emit green (B) light, but implementations of the present specification are not necessarily limited thereto.

FIG. 2 illustrates an example in which a pixel includes only three sub-pixels 21, 22, and 23, but implementations of the present specification are not limited thereto, and the pixel can include four sub-pixels. When the pixel includes four sub-pixels, the pixel can further include a fourth sub-pixel provided to emit white (W) light.

Each of the first to third sub-pixels 21, 22, and 23 can be provided to have the same size. For example, each of the first to third sub-pixels 21, 22, and 23 can be provided to have the same width and the same height. Here, the width can refer to a horizontal direction (a first direction DR1) based on FIG. 1, and the height can refer to a direction (a second direction DR2) perpendicular to the width based on FIG. 1, but implementations of the present specification are not limited thereto.

The sub-pixels 21, 22, and 23 can include emission areas EA1, EA2, and EA3 and non-emission areas NEA1, NEA2, and NEA3, respectively. The first sub-pixel 21 can include a first emission area EA1 and a first non-emission area NEA1 around the first emission area EA1, the second sub-pixel 22 can include a second emission area EA2 and a second non-emission area NEA2 around the second emission area EA2, and the third sub-pixel 23 can include a third emission area EA3 and a third non-emission area NEA3 around the third emission area EA3. Each of the emission areas EA1, EA2, and EA3 can be the same as areas exposed from banks BK of the first electrodes 41a, 41b, and 41c, which will be described below.

The first electrodes 41a, 41b, and 41c are patterned for each sub-pixel 21, 22, and 23. That is, one first electrode 41a is formed in the first sub-pixel 21, the other first electrode 41b is formed in the second sub-pixel 22, and another first electrode 41c is formed in the third sub-pixel 23. The first electrodes 41a, 41b, and 41c can serve as positive electrodes (or anode electrodes) of the display device 1. In some implementations, the first electrode can include reflective electrodes 42a, 42b, and 42c of FIG. 2.

The first electrode 41 and the reflective electrodes 42a, 42b, and 42c can be disposed in each sub-pixel 21, 22, and 23. The first electrode 41 can include the first electrode 41a disposed in the first sub-pixel 21, the first electrode 41b disposed in the second sub-pixel 22, and the first electrode 41c disposed in the third sub-pixel 23, and the reflective electrodes 42a, 42b, and 42c can include a first reflective electrode 42a disposed in the first sub-pixel 21, a second reflective electrode 42b disposed in the second sub-pixel 22, and a third reflective electrode 42c disposed in the third sub-pixel 23.

The bank BK to be described below can be disposed on each of the first electrodes 41a, 41b, and 41c. The bank BK can be provided to cover an edge of the first electrodes 41a, 41b, and 41c disposed in the first to third sub-pixels 21, 22, and 23, respectively, to distinguish the first sub-pixel 21, the second sub-pixel 22, and the third sub-pixel 23. The bank BK can be disposed in the non-emission areas NEA1, NEA2, and NEA3.

The display device 1 can further improve light extraction efficiency using microcavity characteristics by including the reflective electrodes 42a, 42b, and 42c with different surface heights for each sub-pixel 21, 22, and 23.

The microcavity characteristic is a characteristic that, when distances between the reflective electrodes 42a, 42b, and 42c and the second electrode 6 are an integer multiple of a half wavelength (λ/2) of light emitted from the sub-pixels 21, 22 and 23, constructive interference occurs to amplify the light, and when a reflection and re-reflection process is repeated between the reflective electrodes 42a, 42b, and 42c and the second electrode 6, a degree of amplified light continuously increases, thereby increasing the external extraction efficiency of light. The second electrode 6 can serve as a negative electrode (or a cathode electrode).

The common emission layer 5 can be provided to emit white light. For example, the common emission layer 5 can be provided to emit white light by having a two-stack structure including a blue emission layer, a yellow-green emission layer, and a charge generation layer or a three-stack structure including a blue emission layer, a green emission layer, a red emission layer, and a charge generation layer, but is not necessarily limited thereto, and can be formed of multiple layers exceeding 3 stacks as long as it can emit white light.

The common emission layer 5 can be formed as a common layer across the first to third sub-pixels 21, 22, and 23.

The second electrode 6 can be disposed on an upper surface of the common emission layer 5, which is opposite to a lower surface of the common emission layer 5 in contact with the first electrodes 41a, 41b, and 41c, and provided as a common layer across the first to third sub-pixels 21, 22, and 23.

In the case of the top emission type, the second electrode 6 can be provided as a cathode electrode, but in the case of the bottom emission type, the second electrode 6 can be provided as an anode electrode including a reflective material. In the case of the top emission type, the second electrode 6 can be formed as a translucent electrode to increase light extraction efficiency using the microcavity characteristic. Since the display device 1 increases light extraction efficiency using the microcavity characteristic in the top emission type, an example in which the second electrode 6 is formed as the translucent electrode will be described.

A color filter layer 9 is provided in each of the first to third sub-pixels 21, 22, and 23 to block a specific color from light emitted from the emission layer 5 of each sub-pixel 21, 22, or 23. A first color filter 91 provided in the first sub-pixel 21 can be provided to block light of other colors excluding red (R) light. In this case, the first color filter 91 can be provided as a red color filter. A second color filter 92 provided in the second sub-pixel 22 can be provided to block light of other colors excluding green (G) light. In this case, a second color filter 92 can be provided as a green color filter. A third color filter 93 provided in the third sub-pixel 23 can be provided to block light of other colors excluding blue (B) light. In this case, the third color filter 93 can be provided as a blue color filter. However, implementations of the present specification are not limited thereto.

The first to third color filters 91, 92, and 93 provided in the first to third sub-pixels 21, 22, and 23, respectively, can be provided in the same size as the respective sub-pixels or provided by being reduced or expanded at a predetermined ratio to each sub-pixel.

Hereinafter, the stacking structure of the display device 1 will be described in detail.

The display device 1 can include the substrate 2, the insulating layer 3, the first electrodes 41a, 41b, and 41c, the bank BK, the common emission layer 5, the second electrode 6, a capping layer 7, an encapsulation layer 8, and the color filter layer 9.

The substrate 2 can be a plastic film, a glass substrate, or a semiconductor substrate, such as silicon.

The substrate 2 can be formed of a transparent material or an opaque material. The first sub-pixel 21, the second sub-pixel 22, and the third sub-pixel 23 are provided on the substrate 2. The first sub-pixel 21 can be provided to emit red (R) light, the second sub-pixel 22 can be provided to emit blue (B) light, and the third sub-pixel 23 can be provided to emit green (G) light.

The display device 1 can be configured in a so-called top emission type in which the emitted light is emitted upward, and thus both a transparent material and an opaque material can be used as a material of the substrate 2. Color filters 91, 92, and 93 can be respectively provided above the first to third sub-pixels 21, 22, and 23 from which light is emitted to transmit light of the above colors.

The insulating layer 3 is formed on the substrate 2. The insulating layer 3 can include an inorganic insulation material. The insulating layer 3 can include a first insulating layer 3a, a second insulating layer 3b on the first insulating layer 3a, and a third insulating layer 3c on the second insulating layer 3b.

The insulating layer 3 includes circuit elements including at least one thin film transistor TR, various signal lines, and capacitors for each sub-pixel 21, 22, and 23. The thin film transistor TR can be disposed within the first insulating layer 3a. The signal lines can include a gate line, a data line, a power line, and a reference voltage line, and the thin film transistor TR can include a switching transistor, a driving transistor, and a sensing transistor. Each of the sub-pixels 21, 22, and 23 is defined by an intersection structure of gate lines and data lines. The insulating layer 3 can surround the thin film transistors TR.

The switching transistor is switched according to a gate signal supplied to the gate line to supply a data voltage supplied from the data line to the driving transistor.

The driving transistor is switched in response to the data voltage supplied from the switching transistor to generate a data current from the power supplied from the power line and supplies the data current to the first electrodes 41a, 41b, and 41c.

The sensing transistor serves to detect a threshold voltage deviation of the driving transistor, which causes the degradation of image quality, and supplies the current of the driving transistor to the reference line in response to a sensing control signal supplied from the gate line or a separate sensing line.

The capacitor serves to maintain the data voltage supplied to the driving transistor for one frame and is connected to each of a gate terminal and a source terminal of the driving transistor.

A first thin film transistor TR, a second thin film transistor TR, and a third thin film transistor TR are disposed in each sub-pixel 21, 22, and 23 within the first insulating layer 3a. The first thin film transistor TR can be connected to the first electrodes 41a, 41b, and 41c disposed on the first sub-pixel 21 to apply a driving voltage for emitting light of a color corresponding to the first sub-pixel 21. The first thin film transistor TR, the second thin film transistor TR, and the third thin film transistor TR can be disposed on the same thin film transistor layer, but implementations of the present specification are not limited thereto.

The second thin film transistor TR can be connected to the first electrodes 41a, 41b, and 41c disposed on the second sub-pixel 22 to apply a driving voltage for emitting light of a color corresponding to the second sub-pixel 22.

The third thin film transistor TR can be connected to the first electrodes 41a, 41b, and 41c disposed on the third sub-pixel 23 to apply a driving voltage for emitting light of a color corresponding to the third sub-pixel 23.

Each of the first sub-pixel 21, the second sub-pixel 22, and the third sub-pixel 23 supplies a predetermined current to the emission layer in response to the data voltage of the data line when receiving a gate signal (or a scan signal) from the gate line (or the scan line) using each transistor TR. Accordingly, the light-emitting layer of each of the first sub-pixel 21, the second sub-pixel 22, and the third sub-pixel 23 can emit light with a predetermined brightness according to the predetermined current.

The insulating layer 3 can protect the transistors TR. The insulating layer 3 can be formed of an inorganic insulating material, but is not necessarily limited thereto and can be formed of an organic insulating material. For example, the insulating layer 3 can be formed of an inorganic material, such as silicon nitride (SiNₓ), silicon oxide (SiOₓ), aluminum oxide (Al₂O₃), or the like, but implementations of the present specification are not limited thereto. The first insulating layer 3a, the second insulating layer 3b, and the third insulating layer 3c can be formed of an inorganic material, such as silicon nitride (SiNₓ), silicon oxide (SiOₓ), aluminum oxide (Al₂O₃), etc., but implementations of the present specification are not limited thereto.

A plurality of conductive layers can be disposed on the insulating layer 3. The conductive layers can include a first conductive layer on the first insulating layer 3a, a second conductive layer on the second insulating layer 3b, and a third conductive layer on the third insulating layer 3c. The first conductive layer can include a first reflective electrode 42a and a first connection electrode 42a′, the second conductive layer can include a second reflective electrode 42b and a second connection electrode 42b', and the third conductive layer can include a third reflective electrode 42c and a third connection electrode 42c′. The first reflective electrode 42a and the first connection electrode 42a′ can be disposed on the same layer and can include the same material. The second reflective electrode 42b and the second connection electrode 42b′ can be disposed on the same layer and can include the same material. The third reflective electrode 42c and the third connection electrode 42c′ can be disposed on the same layer and can include the same material.

Each conductive layer can include a reflective material for reflecting light. For example, the reflective material can be a metal, but is not necessarily limited thereto, and can be other materials as long as it can reflect light. For example, the reflective material can include aluminum (Al) or silver (Ag), but implementations of the present specification are not limited thereto.

Since the reflective electrodes 42a, 42b, and 42c are disposed below the common emission layer 5 for emitting light, the reflective electrode 42 can reflect the light emitted upward from the common emission layer 5. Here, the term “upward” can be a direction in which a user can perceive light, for example, a side to which the encapsulation layer 8 or the color filter layer 9 is disposed. Accordingly, it is possible to further increase the light efficiency of the first sub-pixel 21, the second sub-pixel 22, and the third sub-pixel 23 compared to a case in which there are no reflective electrodes 42a, 42b, and 42c, and the user can perceive an image with high brightness, that is, clear image, through the increased light efficiency.

In the first emission area EA1 and the first non-emission area NEA1 of the first sub-pixel 21, the first reflective electrode 42a can be disposed on the upper surface and side surfaces of the first insulating layer 3a and the substrate 2 exposed by the first insulating layer 3a. That is, as illustrated in FIG. 3, since the first insulating layer 3a is disposed in the non-emission areas NEA1, NEA2, and NEA3, on the first non-emission area NEA1, the first reflective electrode 42a is disposed on the first insulating layer 3a, but on the first emission area EA, the first reflective electrode 42a can be disposed between the first insulating layers 3a respectively disposed in the adjacent first non-emission areas NEA1. In the second emission area EA2 and the second non-emission area NEA2 of the second sub-pixel 22, the second reflective electrode 42b can be disposed on the first insulating layer 3a, and in the third emission area EA3 and the third non-emission area NEA3 of the third sub-pixel 23, the third reflective electrode 42c can be disposed on the first insulating layer 3a. In each non-emission area NEA1, NEA2, and NEA3, the first reflective electrode 42a and the first connection electrode 42a′ can be electrically connected to each transistor TR.

Meanwhile, the first insulating layer 3a can be disposed in the non-emission areas NEA1, NEA2, and NEA3 as illustrated in FIGS. 3, 4, 5, and 6. In some implementations, the first insulating layer 3a is not be disposed in the emission areas EA1, EA2, and EA3, but implementations of the present specification are not limited thereto, and the first insulating layer 3a can be disposed in some of the emission areas EA1, EA2, and EA3. Hereinafter, for convenience of description, a case in which the first insulating layer 3a is not disposed in the emission areas EA1, EA2, and EA3 and exposes the substrate 2 on the emission areas EA1, EA2, and EA3 will be described.

The first reflective electrode 42a and the first connection electrode 42a′ disposed on the first insulating layer 3a can be disposed on the upper surface of the first insulating layer 3a and the side surface of the first insulating layer 3a, respectively. In addition, in some implementations, the first reflective electrode 42a and the first connection electrode 42a′ dos not overlap the first insulating layer 3a in the emission areas EA1, EA2, and EA3 in which the first insulating layer 3a is not disposed. For example, the first reflective electrode 42a and the first connection electrode 42a′ can be in contact with the upper surface of the substrate 2 in the emission areas EA1, EA2, and EA3 in which the first insulating layer 3a is not disposed. When a separate layer is present between the first insulating layer 3a and the substrate 2, the first reflective electrode 42a and the first connection electrode 42a′ can be in contact with the separate layer in the emission areas EA1, EA2, and EA3 in which the first insulating layer 3a is not disposed. In the present specification, the side surface of the first insulating layer 3a can be an inclined surface of the first insulating layer 3a illustrated in FIGS. 4 to 6. The first reflective electrode 42a and the first connection electrode 42a′ can be in direct contact with the first insulating layer 3a.

Since an area of the first connection electrode 42a′ is smaller than that of the first reflective electrode 42a, the first connection electrode 42a′ can be disposed in only portions of the second and third emission areas EA2 and EA3 as illustrated in FIGS. 5 and 6. In some implementations, the first connection electrode 42a′ does not overlap the second and third emission areas EA2 and EA3.

The second insulating layer 3b can be disposed on the first reflective electrode 42a and the first connection electrode 42a′. The second insulating layer 3b can have a step caused by the thicknesses of the first reflective electrode 42a and the first connection electrode 42a′.

As illustrated in FIG. 3, in an area not in contact with the connection electrode (or the reflective electrode) of each sub-pixel, the second insulating layer 3b can completely cover the first reflective electrode 42a.

On the other hand, as illustrated in FIG. 4, in the area not in contact with the connection electrode (or the reflective electrode) of each sub-pixel (area in which the first reflective electrode 42a is in contact with the second connection electrode 42b′), the second insulating layer 3b can expose an upper surface of the first reflective electrode 42a. The first insulating layer 3a can be disposed in an area in which the first reflective electrode 42a is in contact with the second connection electrode 42b′, and the first reflective electrode 42a overlapping the first insulating layer 3a can protrude farther upward than the first reflective electrode 42a not overlapping the first insulating layer 3a due to the first insulating layer 3a. That is, the second insulating layer 3b can be disposed on the remaining area of the second reflective electrode 42a excluding the area of the second reflective electrode 42a, which is in direct contact with the second connection electrode 42b′. The second connection electrode 42b′ and the third connection electrode 42c′ can overlap the first insulating layer 3a.

As illustrated in FIG. 5, in the area not in contact with the connection electrode (or the reflective electrode) of each sub-pixel (area in which the first connection electrode 42a′ is in contact with the second reflective electrode 42b), the second insulating layer 3b can expose an upper surface of the first connection electrode 42a′. The first insulating layer 3a can be disposed in an area in which the first connection electrode 42a′ is in contact with the second reflective electrode 42b, and the first connection electrode 42a′ overlapping the first insulating layer 3a can protrude farther upward than the first connection electrode 42a′ not overlapping the first insulating layer 3a due to the first insulating layer 3a. That is, the second insulating layer 3b can be disposed on the remaining area of the first connection electrode 42a′ excluding the area of the first connection electrode 42a′, which is in direct contact with the second reflective electrode 42b.

As illustrated in FIG. 6, in the area not in contact with the connection electrode (or the reflective electrode) of each sub-pixel (area in which the first connection electrode 42a′ is in contact with the second connection electrode 42b′), the second insulating layer 3b can expose the upper surface of the first connection electrode 42a′. The first insulating layer 3a can be disposed in the area in which the first connection electrode 42a′ is in contact with the second connection electrode 42b′, and the first connection electrode 42a′ overlapping the first insulating layer 3a can protrude farther upward than the first connection electrode 42a′ not overlapping the first insulating layer 3a due to the first insulating layer 3a. That is, the second insulating layer 3b can be disposed on the remaining area of the first connection electrode 42a′ excluding the area of the first connection electrode 42a′, which is in direct contact with the second connection electrode 42b′.

The second reflective electrode 42b or the second connection electrode 42b′ can be disposed on the second insulating layer 3b. The second reflective electrode 42b can be disposed in the second sub-pixel 22, and the second connection electrode 42b′ can be disposed in the first sub-pixel 21 and the third sub-pixel 23.

As illustrated in FIG. 4, the second connection electrode 42b′ can be disposed in the first non-emission area NEA1 and can be in direct contact with the upper surface of the first reflective electrode 42a exposed by the second insulating layer 3b. That is, no layer can be disposed between the first reflective electrode 42a and the second connection electrode 42b′.

As illustrated in FIG. 5, the second reflective electrode 42b can be disposed in the second non-emission area NEA2 and the emission area EA2 and can be in direct contact with the upper surface of the first connection electrode 42a′ exposed by the second insulating layer 3b. That is, no layer can be disposed between the second reflective electrode 42b and the first connection electrode 42a′.

As illustrated in FIG. 6, the second connection electrode 42b′ can be disposed in the third non-emission area NEA3 and can be in direct contact with the upper surface of the first connection electrode 42a′ exposed by the second insulating layer 3b. That is, no layer can be disposed between the second connection electrode 42b′ and the first connection electrode 42a′.

The third insulating layer 3c can be disposed on the second reflective electrode 42b and the second connection electrode 42b′.

The third reflective electrode 42c and the third connection electrode 42c′ can be disposed on the third insulating layer 3c.

As illustrated in FIG. 4, in the first non-emission area NEA1, the third connection electrode 42c′ can be electrically connected to the second connection electrode 42b′ through the third insulating layer 3c.

As illustrated in FIG. 5, in the second non-emission area NEA2, the third connection electrode 42c′ can be electrically connected to the second reflective electrode 42b through the third insulating layer 3c.

As illustrated in FIG. 6, in the third non-emission area NEA3, the third reflective electrode 42c can be electrically connected to the second connection electrode 42b′ through the third insulating layer 3c.

The first electrode 41 can be disposed on the third reflective electrode 42c and the third connection electrode 42c′.

Although not illustrated, a trench can be formed in the insulating layer 3. For example, the trench can be formed in the non-emission areas NEA1, NEA2, and NEA3. The trench can be formed by passing through portions of the third insulating layer 3c and the second insulating layer 3b, but implementations of the present specification are not limited thereto. Since the trench is formed between adjacent sub-pixels 21, 22, and 23, a lateral leakage current (LLC) due to the common emission layer 5 between the adjacent sub-pixels 21, 22, and 23 can be improved in the display device 1.

As illustrated in FIG. 3, the first electrodes 41a, 41b, and 41c can be disposed in each of the sub-pixels 21, 22, and 23. The first electrodes 41a, 41b, and 41c can be disposed on the same layer and can include the same material.

As illustrated in FIG. 3, in the emission areas EA1, EA2, and EA3, distances between the reflective electrodes 42a, 42b, and 42c and the second electrode 6 can be different. For example, a separation distance between the first reflective electrode 42a and the second electrode 6 can be the largest, followed by a separation distance between the second reflective electrode 42b and the second electrode 6, and finally, a separation distance between the third reflective electrode 42c and the second electrode 6 can be the smallest.

In this way, the reason why the reflective electrodes 42a, 42b, and 42c are formed to have various spacing distances (or resonance distances) from the second electrode 6 is that the light extraction efficiency of different colors can be increased through reflection and re-reflection between the reflective electrodes 42a, 42b, and 42c and the second electrode 6 according to the spacing distances. Accordingly, it is possible to increase the light extraction efficiency of red light in the first sub-pixel 21, increase the light extraction efficiency of green light in the second sub-pixel 22, and increase the light extraction efficiency of blue light in the third sub-pixel 23.

In the third emission area EA3 of the third sub-pixel 23, the first electrode 41c can be disposed directly on the third reflective electrode 42c. In each of the non-emission areas NEA1 and NEA2 of the first and second sub-pixels 21 and 22, the first electrodes 41a and 41b can be disposed directly on the second connection electrode 42c′.

Each of the first electrodes 41a, 41b, and 41c can be electrically connected to the thin film transistor TR in each of the non-emission areas NEA1, NEA2, and NEA3.

The first electrodes 41a, 41b, and 41c can include a material with high light transmittance. For example, the first electrodes 41a, 41b, and 41c can include ITO, IZO, or TiN, but are not limited thereto.

The bank BK can be disposed on the first electrodes 41a, 41b, and 41c. The bank BK can be formed of an inorganic material, such as silicon nitride (SiNₓ), silicon oxide (SiOₓ), aluminum oxide (Al₂O₃), etc., but implementations of the present specification are not limited thereto. The banks BK can be disposed on the non-emission areas NEA1, NEA2, and NEA3.

In the emission areas EA1, EA2, and EA3, the banks BK can expose the upper surfaces of the first electrodes 41a, 41b, and 41c to define the emission areas EA1, EA2, and EA3. The bank BK can be in contact with the upper surfaces of the first electrodes 41a, 41b, and 41c and the side surfaces of the first electrodes 41a, 41b, and 41c. In the non-emission areas NEA1, NEA2, and NEA3, the bank BK can completely cover the upper surfaces of the first electrodes 41a, 41b, and 41c, and in the emission areas EA1, EA2, and EA3, the bank BK can expose the upper surfaces of the first electrodes 41a, 41b, and 41c.

The common emission layer 5 is formed on the first electrodes 41a, 41b, and 41c and the bank BK. The common emission layer 5 can be in contact with the upper surfaces of the first electrodes 41a, 41b, and 41c. The common emission layer 5 can be in direct contact with the upper surfaces of the first electrodes 41a, 41b, and 41c, the upper surface and side surfaces of the bank BK, and the upper surface of the insulating layer 3. The common emission layer 5 can also be disposed to extend to the trench.

In some implementations, an organic light emitting diode (OLED) of the pixel can include the first electrode 41 or ANO, the second electrode 6 or CAT, and the common emission layer 5 between the first electrode 41 and the second electrode 6.

The common emission layer 5 can be provided to emit white (W) light. To this end, the common emission layer 5 can include a plurality of stacks for emitting light of different colors. Specifically, the common emission layer 5 can include a first stack, a second stack, and a charge generation layer CGL provided between the first stack and the second stack.

The second electrode 6 is formed on the common emission layer 5. The second electrode 6 can serve as a cathode of the display device 1. Like the common emission layer 5, the second electrode 6 is formed in each of the sub-pixels 21, 22, and 23 and between the sub-pixels 21, 22, and 23.

In the display device 1, the second electrode 6 can be formed as a translucent electrode to implement white light with light efficiency in the top emission type. Accordingly, the microcavity effect can be obtained for each of the first to third sub-pixels 21, 22, and 23. As reflection and re-reflection of light are repeated between the second electrode 6 and the reflective electrodes 42a, 42b, and 42c, it is possible to obtain the microcavity effect, thereby increasing light extraction efficiency.

Meanwhile, since the second electrode 6 is formed on the upper surface of the common emission layer 5, the second electrode 6 can be formed along a profile of the common emission layer 5. Since the common emission layer 5 is formed along the profiles of the first electrodes 41a, 41b, and 41c in the emission areas, the second electrode 6 can be formed along the profiles of the first electrodes 41a, 41b, and 41c. In addition, the capping layer 7 on the second electrode 6 can also be formed along a profile of the second electrode 6.

The capping layer 7 can be formed of an inorganic insulation material, but is not limited thereto. The capping layer 7 can be disposed on the second electrode 6 to protect the organic light emitting diode.

The encapsulation layer 8 is formed on the second electrode 6 to prevent external moisture from penetrating the common emission layer 5. The encapsulation layer 8 can be formed of an inorganic insulation material or formed in a structure in which an inorganic insulation material and an organic insulation material are alternately stacked, but is not necessarily limited thereto.

The color filter layer 9 is formed on the encapsulation layer 8. The color filter layer 9 can include the red (R) first color filter 91 provided in the first sub-pixel 21, the blue (B) second color filter 92 provided in the second sub-pixel 22, and the green (G) third color filter 93 provided in the third sub-pixel 23, but is not necessarily limited thereto.

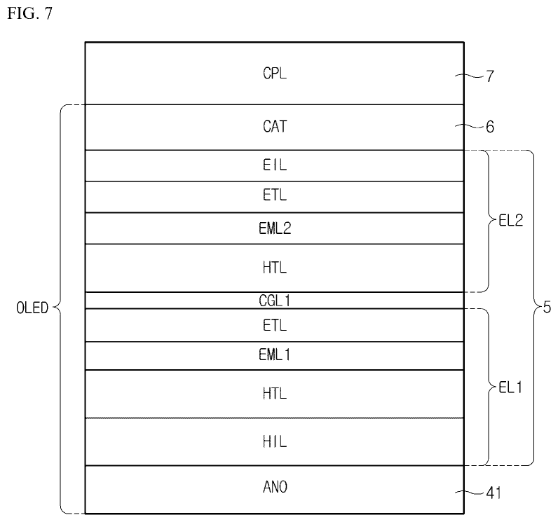

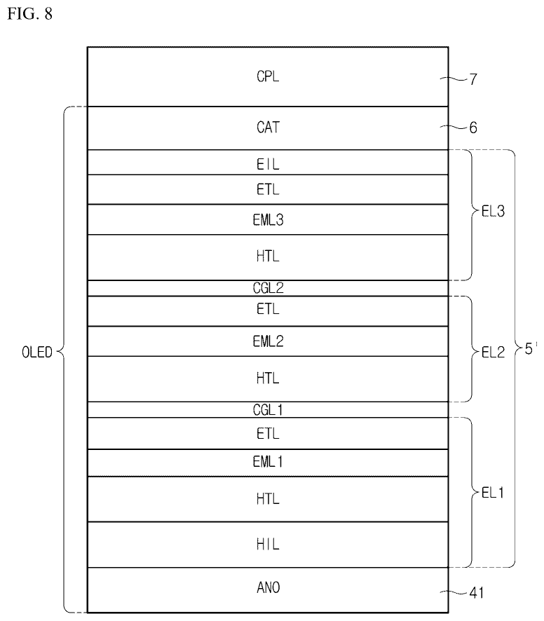

FIG. 7 is a cross-sectional view of one implementation of an organic light emitting diode (OLED) of a pixel. FIG. 8 is a cross-sectional view of another implementation of an organic light-emitting diode (OLED) of pixel.

Referring to FIGS. 1 to 8, the common emission layer 5 can include a first stack EL1 provided on the first electrodes 41a, 41b, and 41c, a second stack EL2, and a first charge generation layer CGL1.

The first stack EL1 can be provided on the first electrodes 41a, 41b, and 41c and formed in a structure in which a hole injecting layer HIL, a hole transporting layer HTL, a blue (B) emitting layer EML1, and an electron transporting layer ETL can be stacked sequentially.

The first stack EL1 can be disposed between the first sub-pixel 21 and the second sub-pixel 22 and between the second sub-pixel 22 and the third sub-pixel 23.

The first charge generation layer CGL1 serves to supply charges to the first stack EL1 and the second stack EL2. The first charge generation layer CGL1 can include an N-type charge generation layer for supplying electrons to the first stack EL1 and a P-type charge generation layer for supplying holes to the second stack EL2. The N-type charge generation layer can include a metallic material as a dopant.

The second stack EL2 can be provided on the first stack EL1 and configured in a structure in which a hole transporting layer HTL, a yellow-green (YG) light-emitting layer EML2, an electron transporting layer ETL, and an electron injecting layer EIL are sequentially stacked.

The second stack EL2 can be disposed between the first sub-pixel 21 and the second sub-pixel 22 and between the second sub-pixel 22 and the third sub-pixel 23.

As a result, the common light-emitting layer 5 can be provided as a common layer across the first to third sub-pixels 21, 22, and 23 as illustrated in FIG. 3.

As illustrated in FIGS. 3 to 8, a common emission layer 5′ of the organic light emitting diode (OLED) of the pixel can include the first stack EL1 provided on the first electrodes 41a, 41b, and 41c, the second stack EL2, a third stack EL3, the first charge generation layer CGL1 between the first stack EL1 and the second stack EL2, and a second charge generation layer CGL2 between the second stack EL2 and the third stack EL3.

The first stack EL1 can be provided on the first electrodes 41a, 41b, and 41c and formed in a structure in which a hole injecting layer HIL, a hole transporting layer HTL, a blue (B) emitting layer EML1, and an electron transporting layer ETL are sequentially stacked.

The first stack EL1 can be disposed between the first sub-pixel 21 and the second sub-pixel 22 and between the second sub-pixel 22 and the third sub-pixel 23, that is, on the bank BK.

The first charge generation layer CGL1 serves to supply charges to the first stack EL1 and the second stack EL2. The first charge generation layer CGL1 can include an N-type charge generation layer for supplying electrons to the first stack EL1 and a P-type charge generation layer for supplying holes to the second stack EL2. The N-type charge generation layer can include a metallic material as a dopant.

The second stack EL2 can be provided on the first stack EL1 and configured in a structure in which a hole transporting layer HTL, a green (G) light-emitting layer EML2, and an electron transporting layer ETL are sequentially stacked.

The second stack EL2 can be disposed between the first sub-pixel 21 and the second sub-pixel 22 and disposed between the second sub-pixel 22 and the third sub-pixel 23, that is, on the bank BK.

The second charge generation layer CGL2 serves to supply charges to the second stack EL2 and the third stack EL3. The second charge generation layer CGL2 can include an N-type charge generation layer for supplying electrons to the second stack EL2 and a P-type charge generation layer for supplying holes to the third stack EL3. The N-type charge generation layer can include a metallic material as a dopant.

The third stack EL3 can be provided on the second stack EL2 and configured in a structure in which a hole transporting layer HTL, a red (R) light-emitting layer EML3, an electron transporting layer ETL, and an electron injecting layer EIL are sequentially stacked.

As illustrated in FIGS. 1 to 8, the charge generation layers CGL1 and CGL2 can be disposed between the first sub-pixel 21 and the second sub-pixel 22 and between the second sub-pixel 22 and the third sub-pixel 23. Meanwhile, in the display device 1, since the common emission layer 5 is also disposed between the sub-pixels 21, 22, and 23, when one sub-pixel emits light, a lateral leakage current can flow to the adjacent sub-pixels 21, 22, and 23 through the charge generation layers CGL1 and CGL2, but the trenches can be formed between the sub-pixels 21, 22, and 23. A length of the common emission layer 5 can be increased at the boundaries of the sub-pixels 21, 22, and 23 through the trenches, thereby increasing a current path. Accordingly, it is possible to prevent the occurrence of the lateral leakage current. Furthermore, the common emission layers 5 and 5′ can be separated by the trench, thereby preventing a lateral leakage current.

In the display device 1, the first connection electrode 42a′ (or the first reflective electrode 42a) disposed on each of the sub-pixels 21, 22, and 23 can be disposed on the first insulating layer 3a disposed in the non-emission areas NEA1, NEA2, and NEA3, and the second connection electrode 42b′ (or the second reflective electrode 42b) can be disposed directly on the upper surface of the first connection electrode 42a′ (or the first reflective electrode 42a), thereby reducing the number of contact holes and increasing the aperture ratio of each of the sub-pixels 21, 22, and 23 (increasing the areas of the emission areas EA1, EA2, and EA3).

In addition, since the aperture ratio of each of the sub-pixels 21, 22, and 23 is increased, the performance of the device can be improved, power consumption can be reduced, and the lifetime of the organic light emitting diode (OLED) of the device can be extended.

Hereinafter, a method of manufacturing the display device 1 will be described.

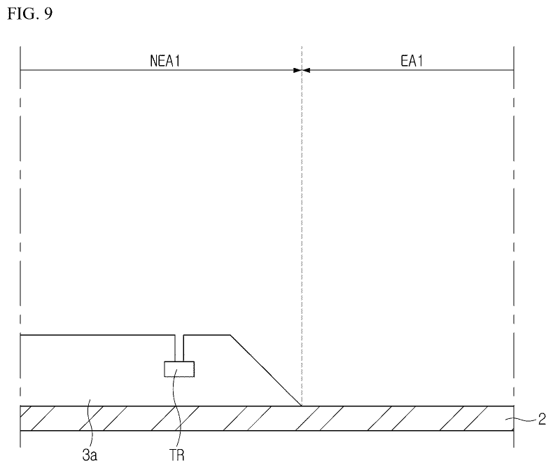

FIGS. 9 through 14 are a sequence of cross-sectional views for method of manufacturing a display device. FIGS. 9 to 14 are illustrated based on the above description of FIG. 4, and the operations described in FIG. 4 can be applied to FIGS. 5 and 6 in substantially the same manner.

Referring to FIGS. 4 and 9, the first insulating layer 3a is formed on the substrate 2. The transistor TR can be disposed within the first insulating layer 3a. A through hole can be formed in an area overlapping the transistor TR above the transistor TR.

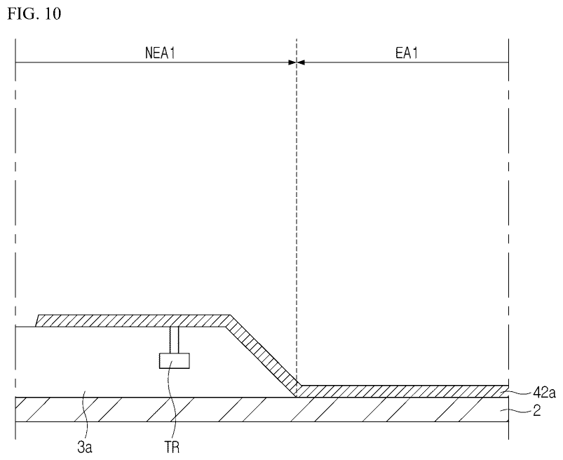

Referring to FIGS. 4 and 10, the first reflective electrode 42a is formed on the first insulating layer 3a and the substrate 2. The first reflective electrode 42a can be electrically connected to the transistor TR in the first non-emission area NEA1. The first reflective electrode 42a can be in direct contact with the upper surface and side surfaces of the first insulating layer 3a and can be in contact with the upper surface of the substrate 2. The first reflective electrode 42a can have a step formed by the first insulating layer 3a.

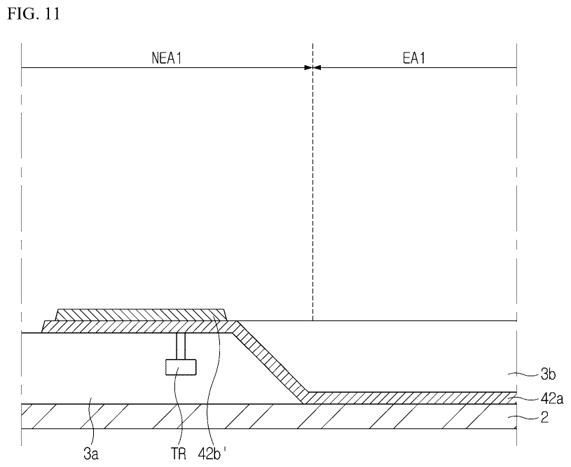

Referring to FIGS. 4 and 11, the second insulating layer 3b is formed on the first reflective electrode 42a. The second insulating layer 3b can be disposed in the first emission area EA1. The second insulating layer 3b can also be disposed in the first non-emission area NEA1, but implementations of the present specification are not limited thereto.

The second connection electrode 42b′ is formed on the first reflective electrode 42a in the first non-emission area NEA1. The second connection electrode 42b′ can be disposed directly on the upper surface of the first reflective electrode 42a.

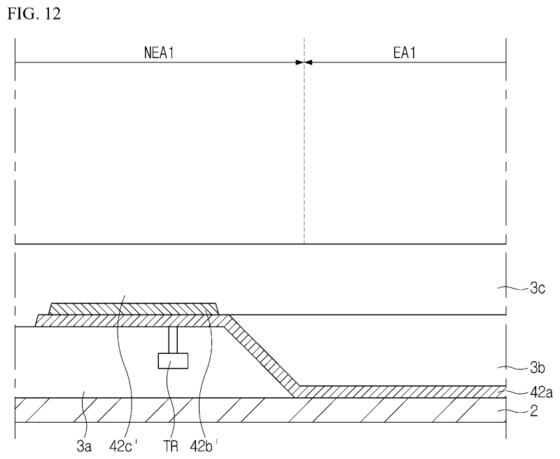

Referring to FIGS. 4 and 12, the third insulating layer 3c is formed on the second connection electrode 42b′ and the second insulating layer 3b.

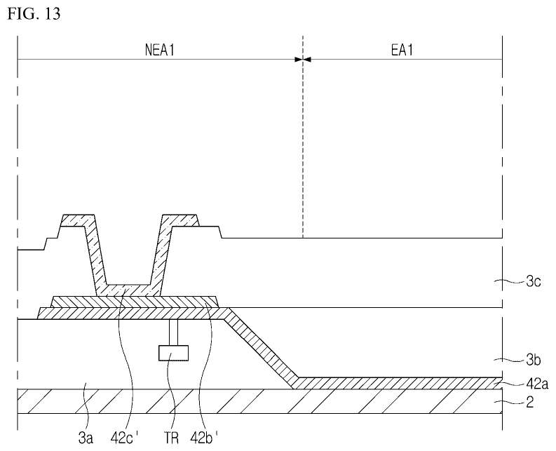

Referring to FIGS. 4 and 13, the third connection electrode 42c′ electrically connected to the second connection electrode 42b′ through the third insulating layer 3c is formed. The third connection electrode 42c′ can overlap the first insulating layer 3a.

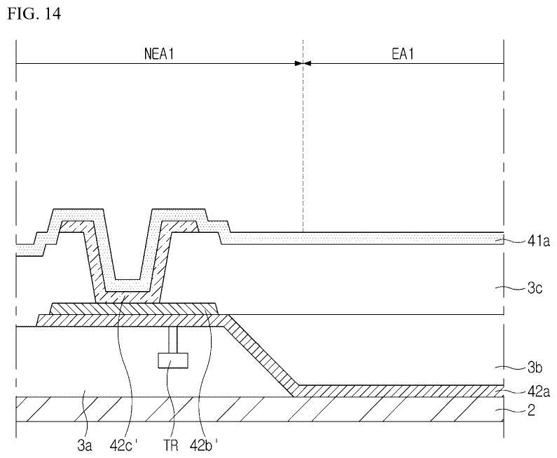

Referring to FIGS. 4 and 14, the first electrode 41a is formed on the third connection electrode 42c′. The first electrode 41a can be disposed directly on the upper surface of the third connection electrode 42c′.

Hereinafter, another implementation of a display device 1_1 will be described.

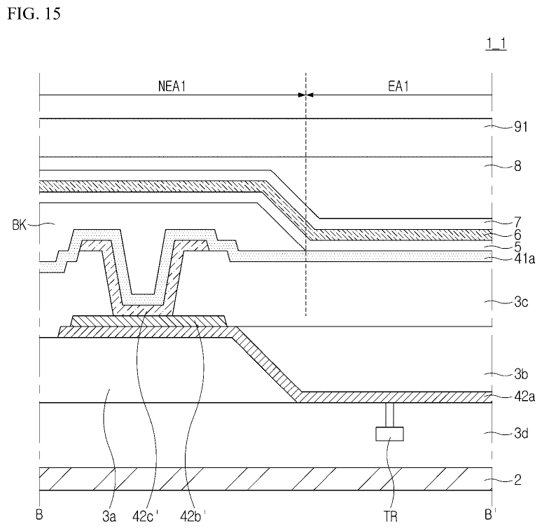

FIG. 15 is a cross-sectional view of another implementation of a pixel along line B-B′ of FIG. 2.

Referring to FIG. 15, the display device 1_1 differs from the display device 1 of FIG. 4 in that the transistor TR is disposed in the first emission area EA1.

More specifically, the display device 1_1 can further include a fourth insulating layer 3d disposed between the substrate 2 and the first insulating layer 3a, and the transistor TR can be disposed in the fourth insulating layer 3d. The transistor TR can be disposed in the first emission area EA1.

Since the remaining parts have been described above in FIG. 4, the detailed descriptions thereof will be omitted.

A display device according to various implementations of the present specification can be described as follows.

According to various implementations of the present specification, there is provided a display device including a substrate on which a first sub-pixel including a first emission area and a first non-emission area surrounding the first emission area is defined, a first insulating layer on the first non-emission area of the substrate, a first reflective electrode disposed on an upper surface and side surfaces of the first insulating layer and disposed in the first emission area and the first non-emission area, a second insulating layer disposed on the first reflective electrode and exposing an upper surface of the first reflective electrode disposed on the first insulating layer, and a second connection electrode disposed directly on the exposed upper surface of the first reflective electrode.

The display device can further include a third insulating layer on the second connection electrode, in which, in the first non-emission area, the third insulating layer can expose an upper surface of the second connection electrode.

In the display device according to various implementations of the present specification, the display device can further include a third connection electrode connected to the exposed upper surface of the second connection electrode.

The display device according to various implementations of the present specification can further define a second sub-pixel including a second emission area and a second non-emission area around the second emission area and further include a first connection electrode disposed on the upper surface and side surfaces of the first insulating layer and disposed in the second emission area and the second non-emission area, in which the first connection electrode can be disposed on the same layer as the first reflective electrode.

In the display device according to various implementations of the present specification, the second insulating layer can expose an upper surface of the first connection electrode in the second non-emission area, and the display device can further include a second reflective electrode on the second insulating layer, in which the second reflective electrode can be connected to the exposed upper surface of the first connection electrode.

In the display device according to various implementations of the present specification, in the second non-emission area, the third insulating layer can expose an upper surface of the second reflective electrode, and the third connection electrode can be connected to the exposed upper surface of the second reflective electrode.

In the display device according to various implementations of the present specification, the second reflective electrode can be disposed on the same layer as the second connection electrode.

The display device according to various implementations of the present specification can further define a third sub-pixel including a third emission area and a third non-emission around the third emission area, in which, in the third non-emission area, the first connection electrode can be disposed on the upper surface and side surfaces of the first insulating layer.

In the display device according to various implementations of the present specification, in the third non-emission area, the second insulating layer can expose the upper surface of the first connection electrode, and in the third non-emission area, the second connection electrode can be connected to the exposed upper surface of the first connection electrode.

In the display device according to various implementations of the present specification, in the third non-emission area, the third insulating layer can expose an upper surface of the second connection electrode, a third reflective electrode can be further disposed on the third insulating layer, and the third reflective electrode can be connected to the exposed upper surface of the second connection electrode.

In the display device according to various implementations of the present specification, the third reflective electrode can be disposed on the same layer as the third connection electrode.

In the display device according to various implementations of the present specification, the first sub-pixel can be a red sub-pixel, the second sub-pixel can be a green sub-pixel, and the third sub-pixel can be a blue sub-pixel.

The display device according to various implementations of the present specification can further include a transistor connected to the first reflective electrode, in which the transistor can overlap the first insulating layer.

The display device according to various implementations of the present specification can further include a transistor connected to the first reflective electrode, and a fourth insulating layer between the substrate and the first insulating layer, in which the transistor can be disposed within the fourth insulating layer.

In the display device according to various implementations of the present specification, the second connection electrode can overlap the first insulating layer.

In some implementations, the first connection electrode (or the first reflective electrode) disposed in each sub-pixel can be disposed on the first insulating layer disposed in the non-emission area, and the second connection electrode can be disposed directly on the upper surface of the first connection electrode (or the first reflective electrode), thereby reducing the number of contact holes and increasing the aperture ratio of each sub-pixel.

In some implementations, the aperture ratio of each sub-pixel can be increased, thereby reducing power consumption and improving the performance of the device.

Implementations of the present specification can therefore provide a low-power display device.

However, effects obtainable from the present specification are not limited to the above-described effects, and other effects that are not mentioned will be able to be clearly understood by those skilled in the art to which the present specification pertains from the following description.

Although implementations of the present specification have been described above with reference to the accompanying drawings, those skilled in the art to which the present specification pertains will be able to understand that the above-described technical configuration can be carried out in other specific forms without changing the technical idea or essential features thereof. Accordingly, it should be understood that the above-described implementations of the present specification are illustrative and not restrictive in all respects.

What is claimed is:

1. A display device comprising:
a substrate comprising a first sub-pixel, wherein the first sub-pixel comprises a first emission area and a first non-emission area around the first emission area;
a first insulating layer disposed on the first non-emission area;
a first reflective electrode disposed on an upper surface and on a side surface of the first insulating layer and disposed in the first emission area and in the first non-emission area;
a second insulating layer disposed on the first reflective electrode and exposing an upper surface of the first reflective electrode disposed on the first insulating layer; and
a second connection electrode disposed directly on the exposed upper surface of the first reflective electrode.

2. The display device of claim 1, further comprising a third insulating layer disposed on the second connection electrode, wherein, in the first non-emission area, the third insulating layer exposes an upper surface of the second connection electrode.

3. The display device of claim 2, further comprising a third connection electrode connected to the exposed upper surface of the second connection electrode.

4. The display device of claim 3, wherein:
the substrate comprises a second sub-pixel, wherein the second sub-pixel comprises a second emission area and a second non-emission area around the second emission area; and
the display device further comprises a first connection electrode disposed on the upper surface and on the side surface of the first insulating layer and disposed in the second emission area and the second non-emission area; and
wherein the first connection electrode is disposed on a same layer as the first reflective electrode.

5. The display device of claim 4, wherein:
the second insulating layer exposes an upper surface of the first connection electrode in the second non-emission area, and
the display device further comprises a second reflective electrode disposed on the second insulating layer, wherein the second reflective electrode is connected to the exposed upper surface of the first connection electrode.

6. The display device of claim 5, wherein, in the second non-emission area, the third insulating layer exposes an upper surface of the second reflective electrode and the third connection electrode is connected to the exposed upper surface of the second reflective electrode.

7. The display device of claim 5, wherein the second reflective electrode is disposed on a same layer as the second connection electrode.

8. The display device of claim 4, further comprising a third sub-pixel including a third emission area and a third non-emission around the third emission area, wherein, in the third non-emission area, the first connection electrode is disposed on the upper surface and on the side surface of the first insulating layer.

9. The display device of claim 8, wherein the second insulating layer exposes an upper surface of the first connection electrode in the third non-emission area, and in the third non-emission area, the second connection electrode is connected to the exposed upper surface of the first connection electrode.

10. The display device of claim 9, wherein, in the third non-emission area, the third insulating layer exposes the upper surface of the second connection electrode, and the display device further comprises a third reflective electrode on the third insulating layer, wherein the third reflective electrode is connected to the exposed upper surface of the second connection electrode.

11. The display device of claim 10, wherein the third reflective electrode is disposed on the same layer as the third connection electrode.

12. The display device of claim 8, wherein the first sub-pixel is a red sub-pixel, the second sub-pixel is a green sub-pixel, and the third sub-pixel is a blue sub-pixel.

13. The display device of claim 1, further comprising a transistor connected to the first reflective electrode, wherein the transistor overlaps the first insulating layer.

14. The display device of claim 1, further comprising: a transistor connected to the first reflective electrode; and a fourth insulating layer between the substrate and the first insulating layer, wherein the transistor is disposed within the fourth insulating layer.

15. The display device of claim 1, wherein the second connection electrode overlaps the first insulating layer.

16. The display device of claim 1, wherein the first insulating layer is not disposed in the first emission area.

17. The display device of claim 1, wherein the first reflective electrode is in direct contact with the first insulating layer.
